(19) United States
(12) Patent Application Publication
(10) Pub. No.: US 2025/0074239 A1
(43) Pub. Date: Mar. 6, 2025

(54) ELECTRIC EQUIPMENT AND VEHICLE

(71) Applicant: TOYOTA JIDOSHA KABUSHIKI KAISHA, Toyota-shi (JP)

(72) Inventors: Yuya AOKI, Miyoshi-shi (JP); Toru ANDO, Obu-shi (JP)

(73) Assignee: TOYOTA JIDOSHA KABUSHIKI KAISHA, Toyota-shi (JP)

(21) Appl. No.: 18/665,990

(22) Filed: May 16, 2024

(30) Foreign Application Priority Data
Aug. 29, 2023 (JP) 2023-138954

(51) Int. Cl. B60L 53/62; B60L 53/66

(52) U.S. Cl. CPC B60L 53/62; B60L 53/66

(57) ABSTRACT

EVSE (electric equipment) externally feeds the power of the battery to the electric load. EVSE externally charges the power of the power grid to the battery. The vehicle-side ECU and ECU are connected by a CPLT signal line. When a short circuit occurs EVSE of the charger/discharger during external power supply or external charge, ECU identifies a short circuit location based on the detected current sensor. Also, from ECU to ECU of the vehicle, information on the point of short circuit is communicated using CPLT signal line.

### CROSS-REFERENCE TO RELATED APPLICATION

This application claims priority to Japanese Patent Application No. 2023-138954 filed on Aug. 29, 2023, incorporated herein by reference in its entirety.

### BACKGROUND

### 1. Technical Field

The present disclosure relates to electric equipment and a vehicle.

### 2. Description of Related Art

Japanese Unexamined Patent Application Publication No. 2017-118684 (JP 2017-118684 A) describes that in an electrified vehicle provided with a power storage device that is externally chargeable, when a stopping condition of external charging is satisfied, potential of a pilot signal that is input to the electrified vehicle from a charging device is changed in accordance with a predetermined pattern. In this JP 2017-118684 A, a changing pattern at the time of full charge and a changing pattern at the time of not full charge are differentiated. It is stated therein that whether or not the power storage device is in a fully charged state can thus be communicated from the electrified vehicle to the charging device.

Using a power storage device installed in a vehicle to supply electric power (external power supply) from the power storage device to an external load (electric load) (e.g., vehicle-to-load (V2L)) is known. When external power supply is performed, it is conceivable to provide equipment that adjusts the external power supply (having an interaction function) between the vehicle and the external load. When short-circuiting occurs between the equipment and the external load, the discharge from the vehicle (power storage device) stops, and the external power supply stops. At this time, it is desirable to identify whether short-circuiting has occurred in the equipment or in the external load, i.e., to identify the short-circuiting location.

When external charging of a power storage device installed in a vehicle is performed, equipment (e.g., a charging station) that adjusts external charging is provided between an external power supply such as a power grid or the like, and the vehicle. When short-circuiting occurs between the equipment and the external power supply, electric power supply to the vehicle (power storage device) stops, and external charging stops. At this time, it is desirable to identify whether short-circuiting has occurred in the equipment or in the external power supply, i.e., to identify a short-circuiting location. JP 2017-118684 A makes no mention of identifying the short-circuiting location.

### SUMMARY

An object of the present disclosure is to enable identifying a short-circuiting location when performing external power feeding or external charging using electric equipment connected to a vehicle equipped with a power storage device.

Electric equipment according to the present disclosure is electric equipment connected between at least one of an electric load and a power grid, and a vehicle equipped with a power storage device.

The electric equipment includes
a first current sensor for detecting a current on a first power line connected to the vehicle,
a second current sensor for detecting a current on a second power line connected to the one of the electric load or the power grid,
a communication unit for performing communication with the vehicle, and a control device.
   When short-circuiting occurs in a circuit including the one of the electric load or the power grid and the electric equipment, the control device identifies a short-circuiting location based on a detection value of the first current sensor and a detection value of the second current sensor, and transmits information of the short-circuiting location to the vehicle by the communication unit.

According to this configuration, the electric equipment is connected between the vehicle and the electric load. Alternatively, the electric equipment is connected between the vehicle and the power grid (external power supply). The first current sensor detects current on the power line connected to the vehicle, and the second current sensor detects current on the power line connected to the electric load or the power grid.

When short-circuiting occurs in a circuit including the electric load (or power grid) and the electric equipment, a short-circuit current flows at the short-circuiting location. Depending on the location where the short-circuit current flows (short-circuiting location), change occurs in the current on the power line connected to the vehicle and the current on the power line connected to the electric load or the power grid. The control device detects the current change by the first current sensor and the second current sensor, and identifies the short-circuiting location. Transmitting the information of the short-circuiting location to the vehicle by the communication unit enables the short-circuiting location to be identified in the vehicle.

Preferably, the control device identifies the short-circuiting location as being the electric load or the power grid, when a current is detected by the first current sensor and the second current sensor by electric power supplied from the power storage device to the electric equipment.

Also, the control device identifies the short-circuiting location as being the electric equipment when a current is detected by the first current sensor alone, by electric power supplied from the power storage device to the electric equipment.

When short-circuiting occurs in the electric device, upon electric power being supplied from the power storage device to the electric equipment, a current flows over the first power line, but no current flows over the second power line. Accordingly, when current is detected only by the first current sensor, the electric equipment can be identified as the short-circuiting location. When short-circuiting occurs in the electric load or the power grid, upon electric power being supplied from the power storage device to the electric equipment, a current flows over the first power line and the second power line. Thus, when current is detected by the first current sensor and the second current sensor, the electric load or the power grid can be identified as the short-circuiting location.

Preferably, the electric equipment is configured such that electric power is exchangeable between the power storage device and the electric equipment when a connector of the electric equipment is connected to an inlet of the vehicle, and also communication is performed with the vehicle using a signal line that is connected when the connector is connected to the inlet.

The communication unit transmits the information regarding the short-circuiting location to the vehicle using the signal line.

Sometimes, a control-pilot (CPLT) signal line may be provided at an inlet of a vehicle equipped with a power storage device, in order to perform charge sessions conforming to IEC61851, and high-level communication (HLC) process stipulated in ISO15118. Using such a CPLT signal line as the signal line enables communication to be performed without providing a signal line separately.

A vehicle according to the present disclosure is a vehicle connected to the electric equipment described above.
The vehicle includes a vehicle-side control device and a notification device.
The vehicle-side control device performs notification regarding the short-circuiting location, based on the information of the short-circuiting location received from the communication unit of the electric equipment.

According to this configuration, a user of the vehicle can be notified of the short-circuiting location.

According to the present disclosure, when external power supply or external charging is performed by using electric equipment connected to a vehicle equipped with a power storage device, a short-circuiting location can be identified.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a schematic configuration of a charge/discharge system according to the present embodiment;

FIG. 2 is a diagram showing a sequence of a short-circuit portion diagnostic process according to the present embodiment;

FIG. 3A is a diagram illustrating a relation between a short-circuit generation point and a current;

FIG. 3B is a diagram illustrating a relation between a short-circuit generation point and a current; and

FIG. 3C is a diagram illustrating a relation between a short-circuit generation point and a current.

### DETAILED DESCRIPTION OF EMBODIMENTS

An embodiment of the present disclosure will be described in detail with reference to the drawings. In the drawings, the same or corresponding parts are denoted by the same reference numerals, and the description thereof will not be repeated.

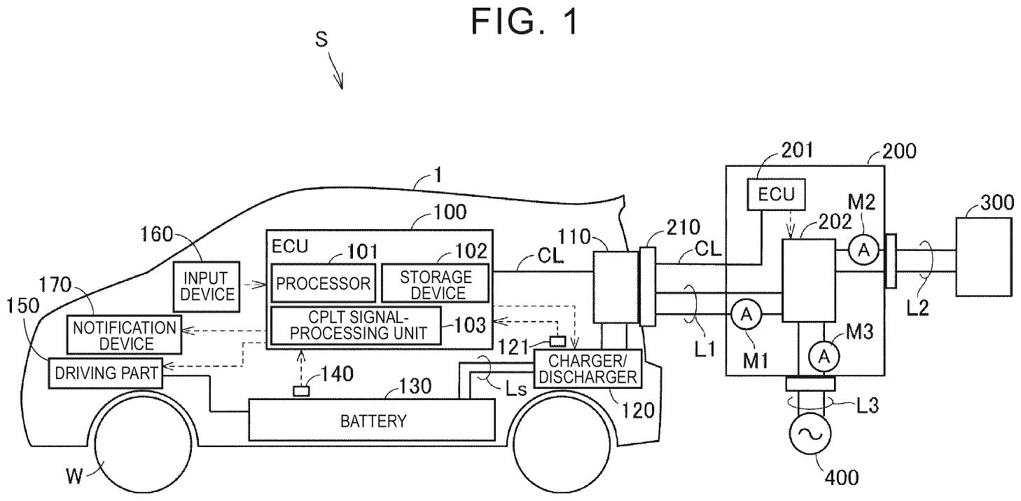

FIG. 1 is a diagram illustrating a schematic configuration of a charge/discharge system S according to the present embodiment. The charge/discharge system S includes a vehicle 1 and electric equipment 200. The vehicle 1 includes a battery 130 that stores electric power for traveling. The battery 130 corresponds to a “power storage device” of the present disclosure. The vehicle 1 may be a battery electric vehicle (BEV) that can travel using only the electric power stored in the battery 130, or a plug-in hybrid electric vehicle (PHEV) that can travel using both the electric power stored in the battery 130 and the power of an engine (not shown).

The battery 130 is a battery pack. The assembled battery includes a plurality of cells electrically connected to each other. The cell may be a lithium-ion battery. The cell may be a secondary battery other than a lithium-ion battery (e.g., a nickel metal hydride battery).

The vehicle 1 includes a vehicle-side Electronic Control Unit (ECU) 100. The vehicle-side ECU 100 is configured to perform charge-control and discharge-control of the battery 130. The vehicle 1 further comprises a monitoring module 140 for monitoring the state of the battery 130. The monitoring module 140 includes a battery sensor that detects a state of a battery pack included in the battery 130, and a signal processing circuit that processes an output signal of the battery sensor. The monitoring module 140 outputs the sensor signal processed by the signal processor to the vehicle-side ECU 100. The battery sensor includes a voltage sensor, a current sensor, and a temperature sensor that respectively detect a voltage, a current, and a temperature of the assembled battery. The vehicle-side ECU 100 may acquire the status of the battery pack (e.g., temperature-current-voltage, SOC (State 25 Of Charge) and the internal-resistance) based on the output of the monitoring module 140.

The vehicle 1 includes an inlet 110 and a charger/discharger 120. The inlet 110 is connectable to a connector 210 of the electric equipment 200. The inlet 110 is connected to the charger/discharger 120 via a power line. The charger/discharger 120 is located between the inlet 110 and the battery 130. The charger/discharger 120 is connected to the battery 130 by a power line Ls. The charger/discharger 120 includes a relay for switching connection/disconnection of a power path from the inlet 110 to the battery 130, and a power conversion circuit (neither of which is shown). In the present embodiment, the power converter includes a DC/AC converter, and converts the DC power of the battery 130 into AC power and supplies the AC power to the inlet 110. Further, the power conversion circuit converts AC power input from the inlet 110 into DC power, and charges the battery 130. Each of the relays and power converters included in the charger/discharger 120 is controlled by a vehicle-side ECU 100.

The vehicle 1 includes a monitoring module 121 that monitors the state of the charger/discharger 120. The monitoring module 121 includes various sensors for detecting the state (e.g., voltage, current, and temperature) of the charger/discharger 120, and outputs the detection result to the vehicle-side ECU 100. In this embodiment, the monitoring module 121 is configured to detect a voltage and a current input to the power conversion circuit and a voltage and a current output from the power conversion circuit.

The vehicle-side ECU 100 includes a processor 101 and a storage device 102. The vehicle-side ECU 100 includes a CPLT processor 103 as a functional block. The processor 101 executes the programs stored in the storage device 102 to perform various types of control in the vehicle-side ECU 100. CPLT signal processor 103 processes a CPLT signal to be described later. The vehicle-side ECU 100 corresponds to an exemplary “vehicle-side control device” of the present disclosure.

The vehicle 1 further includes a travel driving unit 150, an input device 160, a notification device 170, and drive wheels W. The travel driving unit 150 includes a Power Control Unit (PCU) (not shown) and a Motor Generator (MG) (not shown), and is configured to travel the vehicle 1 using electric power stored in the battery 130.

The input device 160 is a device that receives an input from a user. The input device 160 is operated by the user and outputs a signal corresponding to the operation of the user to the vehicle-side ECU 100. The notification device 170 is configured to perform a predetermined notification process to a user (for example, an occupant of the vehicle 1) when requested by the vehicle-side ECU 100. The notification device 170 may be a display device such as a touch-up display. In this case, the touch-up display can also serve as the input device 160 and the notification device 170. The notification device 170 may include at least one of a speaker and a lamp (e.g., a MIL (fault warning lamp)). The notification device 170 may be a meter panel, a head-up display, or a car navigation system.

The charge/discharge system S includes an Electric Vehicle Service Equipment (EVSE) 200. In the present embodiment, EVSE 200 supplies the electric power (the electric power stored in the battery 130) outputted from the charger/discharger 120 to the electric load 300. The electric load 300 may be, for example, a home appliance. In the present disclosure, power supply to the electric load 300 is also referred to as external power supply. The power line L2 of the electric load 300 is connected to EVSE 200 via connectors, thereby enabling external power supply. EVSE 200 also charges the battery 130 with the electric power supplied from the power grid (external power supply) 400 via the charger/discharger 120. In the present disclosure, the charging of the battery 130 using the electric power of the power grid is also referred to as external charging. The power line L3 of the power grid 400 is connected to EVSE 200 via a connector, thereby enabling external charging.

In the present embodiment, EVSE 200 has the functions of external power supply and external charging, but may have only one of the functions of external power supply and external charging. EVSE 200 corresponds to exemplary “electric equipment” of the present disclosure.

EVSE 200 includes ECU 201, power circuit 202, power line L1, and connectors 210. ECU 201 has a configuration similar to that of the vehicle-side ECU 100, and includes a processor, a storage device, and a CPLT signal-processing unit (not shown). ECU 201 is an exemplary “control device” of the present disclosure. The connector 210 is provided at the distal end of the power line L1, and the connector 210 is connected to the inlet 110, so that power can be exchanged between the power circuit 202 and the charger/discharger 120. The power circuit 202 includes a relay for switching the connection/disconnection of the power path between the power line L1 and the power line L2, and a relay for switching the connection/disconnection of the power path between the power line L1 and the power line L3 (both not shown). Further, the power circuit 202 may include a current control circuit that controls a power supply current and a charging current.

ECU 201 controls the connection/disconnection of the relays of the power circuit 202 and the current control circuit. ECU 201 and the connector 210 are connected by a CPLT signal line CL. The inlet 110 and the vehicle-side ECU 100 are also connected by a CPLT signal line CL. By connecting the connector 210 and the inlet 110, the vehicle-side ECU 100 and ECU 201 can transmit and receive signals via CPLT signal line CL. Allow communication CPLT signal line CL and the power line L1 between ECU 201 and the connector 210 are housed in a charge/discharge cable of EVSE 200. CPLT signal line CL is provided to perform communication (information-exchange) defined in IEC61851 or ISO15118. The communication between the vehicle-side ECU 100 and ECU 201 using CPLT signal line CL corresponds to an exemplary “communication unit” of the present disclosure.

The power line L1 is provided with a current sensor M1. The current sensor M1 detects a current flowing through the power line L1. EVSE 200 comprises a current sensor M2. The current sensor M2 detects a current supplied from the power circuit 202 to the power line L2. EVSE 200 comprises a current sensor M3. The current sensor M2 detects a current supplied from the power line L3 to the power circuit 202. The detected current sensor M1, M2, M3 is inputted to ECU 201. The current sensor M1 corresponds to the “first current sensor” of the present disclosure. The current sensor M2 or the current sensor M3 corresponds to an exemplary “second current sensor”.

When the connector 210 is connected to the inlet 110, the vehicle-side ECU 100 and ECU 201 communicate with each other via CPLT signal line CL. Communication via CPLT signal line CL is also referred to as CPLT communication. The vehicle-side ECU 100 and ECU 201 exchange information by CPLT communication. The vehicle-side ECU 100 and ECU 201 start the external power supply when the external power supply is ready. Alternatively, the vehicle-side ECU 100 and ECU 201 initiate external charging when the external charging is ready for both. The vehicle-side ECU 100 and ECU 201 shut off the external power supply when a short circuit occurs in the power circuit between the power line L1 and the electric load 300 during the external power supply. In addition, the vehicle-side ECU 100 and ECU 201 stop the external charging when a short circuit occurs in the power circuit between the power line L1 and the power grid 400 during the external charging. In the present embodiment, when these short-circuits occur, the short-circuit location is identified by using the detected current sensor M1, M2, M3.

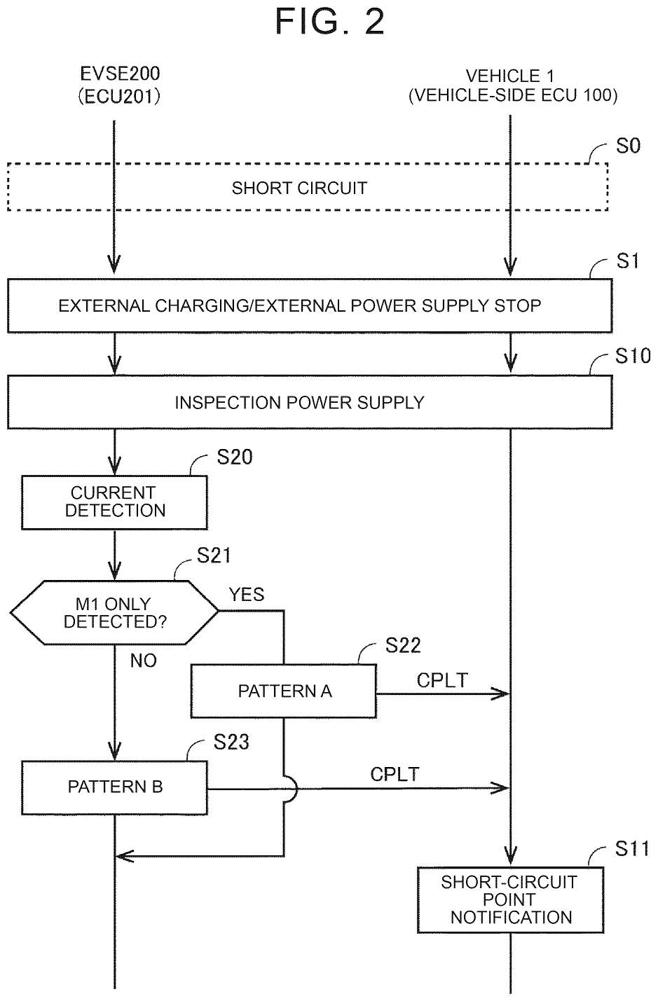

FIG. 2 is a diagram illustrating a sequence of a short-circuit portion diagnosis process according to the present embodiment. When a short circuit occurs in the power circuit between the power line L1 and the electric load 300 or in the power circuit between the power line L1 and the power grid 400 (see step 0, hereinafter, step is abbreviated as “S”), the external power supply/external charge is stopped in S1. The external power supply/external charging is stopped, for example, by shutting off the relays of the charger/discharger 120 and the power circuit 202 and stopping the operation of the power conversion circuit of the charger/discharger 120. Note that the detection of the short circuit may be detected by the charger/discharger 120 and the short circuit detection circuitry provided in EVSE 200, or may be detected based on the input/output power detected by the monitoring module 121. For example, when the current output from the charger/discharger 120 becomes an overcurrent during external power supply, it may be determined that a short circuit has occurred, and when the voltage input to the charger/discharger 120 becomes 0 during external charging, it may be determined that a short circuit has occurred.

Subsequently, test power is supplied from the charger/discharger 120 (S10). In the test power supply, the charger/discharger 120 supplies a predetermined current (predetermined voltage) to EVSE 200 via the power line L1 for a predetermined period of time. EVSE 200 (ECU 201) connects relays of the power path between the power line L1 and the power line L2 when the external power supply is stopped in S1. When the external charge is stopped in S1, EVSE 200 (ECU 201) connects relays of the power path between the power line L1 and the power line L3.

ECU 201 (EVSE 200) detects a current by the current sensor M1 and the current sensor M2 when the relays of the power path between the power line L1 and the power line L2 are connected (when the external power supply is stopped) (S20). ECU 201 detects a current by the current sensor M1 and the current sensor M3 when the relays of the power path between the power line L1 and the power line L3 are connected (when the external charge is stopped) (S20).

ECU 201 determines whether or not a current is detected only in the current sensor M1 at the time of test power supply (S21). When a current is detected only by the current sensor M1, ECU 201 transmits the signal of the butter A to the vehicle-side ECU 100 by CPLT signal line CL (S22). When a current is detected in the current sensor M1 and the current sensor M2 (or the current sensor M1 and the current sensor M3), CPLT signal line CL transmits the signal of the pattern B to the vehicle-side ECU 100.

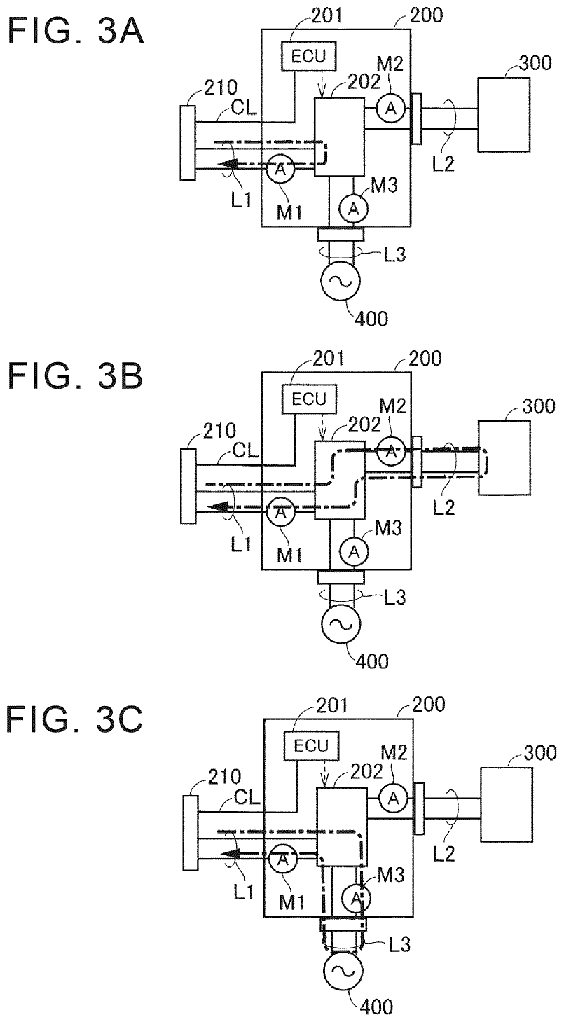

The signal of the pattern A is a signal indicating that a short circuit has occurred in EVSE 200. FIGS. 3A to 3C are diagrams showing a relation between a location where a short circuit occurs and a current. When a short circuit occurs in EVSE 200, a short-circuit current flows through a short-circuit generating portion of EVSE 200. As indicated by the dashed-dotted line in FIG. 3A, a current caused by the test power supply flows through the current sensor M1. The current does not flow through the current sensor M2 and the current sensor M2. When a current is detected only by the current sensor M1, a short circuit occurs in EVSE 200. The signal of the pattern A may set the potential of CPLT signal to a predetermined potential, and the potential of CPLT signal may change in a predetermined pattern. Further, the duty cycle of Pulse Width Modulation (PWM) signal to be superimposed on CPLT signal (change in potential) may be set to a predetermined value.

When the test power supply is performed by connecting the relays of the power paths between the power line L1 and the power line L2, if a short circuit occurs in the electric load 300, a short-circuit current flows through the short-circuit generating portion of the electric load 300. Therefore, as indicated by the dashed-dotted line in FIG. 3B, a current caused by the test power supply flows to the current sensor M1 and the current sensor M2. When a current is detected in the current sensor M1 and the current sensor M2, a short circuit occurs in the electric load 300.

When the test power supply is performed by connecting the relays of the power paths between the power line L1 and the power line L3, if a short circuit occurs in the power grid 400, a short-circuit current flows through the short-circuit generating portion of the power grid 400. Therefore, as indicated by the dashed-dotted line in FIG. 3C, a current caused by the test power supply flows to the current sensor M1 and the current sensor M3. When a current is detected in the current sensor M1 and the current sensor M3, a short circuit occurs in the power grid 400.

The signal of the pattern B is a signal indicating that a short circuit has occurred in the electric load 300 or the power grid 400. The signal of the pattern B may set the potential of CPLT signal to a predetermined potential that differs from the pattern A. The signal of the pattern B may change the potential of CPLT signal in a predetermined pattern that differs from the pattern A. Further, the duty cycle of PWM signal to be superimposed on CPLT signal (change in potential) may be set to a predetermined value around the time of the pattern A.

When the vehicle-side ECU 100 receives the signal of the pattern A or the pattern B via CPLT signal line CL, it notifies the short-circuit portion (S11). The notification of the short-circuited portion is performed using the notification device 170. For example, in a case where the notification device 170 is a display device, when a signal of the pattern A is received, a message indicating “a short circuit has occurred in the electric equipment” is displayed. In addition, when the vehicle-side ECU 100 receives Pattern B, it indicates that “a short circuit has occurred in the connected electric load” or “a short circuit has occurred in the power grid”. At the same time, MIL may be turned on, and a portion where a short circuit occurs may be audibly guided from the speaker.

According to the present embodiment, EVSE 200 is connected between the vehicle 1 and the electric load 300. EVSE 200 is connected between the vehicle 1 and the power grid (external power supply) 400. The current sensor M1 detects a current of a power line connected to the vehicle 1. The detector is inputted to ECU 201. The current sensor M2 detects a current of a power line connected to the electric load 300. The detector is inputted to ECU 201. The current sensor M3 detects a current of a power line connected to the power grid 400. The detector is inputted to ECU 201.

When a short-circuit occurs in a circuit including the electric load 300 (or the power grid 400) and EVSE 200, when the test power is supplied from the charger/discharger 120, a short-circuit current flows at the short-circuit generation point. The current sensor M1 and the current sensor M2 (or the current sensor M3) respond differently depending on the place where the short-circuit current flows (the place where the short-circuit occurs). Accordingly, the short-circuit generation portion can be identified by the current sensor M1 and the current sensor M2 (or the current sensor M3). The short-circuit location is transmitted to the vehicle-side ECU 100 by CPLT signal line CL. As a result, a short-circuit occurrence point is identified in the vehicle 1.

According to the present embodiment, CPLT signal line CL is used to transmit the information of the short-circuited portion (the signals of the pattern A and the pattern B) from the vehicle-side ECU 100 to ECU 201. CPLT signal line CL is provided in advance in order to perform communication (information-exchange) defined in IEC61851 or ISO15118. Therefore, it is possible to transmit the short-circuited portion from the vehicle-side ECU 100 to ECU 201 without providing a new communication line.

In the above-described embodiment, when a short circuit occurs during the external power supply, the external power supply is temporarily stopped, and thereafter, the inspection power supply is performed to identify the short-circuit portion. When a short circuit occurs in EVSE 200 during the external power supply, the current sensor M2 becomes 0, but the current sensor M1 detects the current. When a short circuit occurs in the electric load 300 during external power supply, current is detected in both the current sensor M1 and the current sensor M2. Therefore, when a short circuit occurs during the external power supply, the detection signal of the current sensor M1 and the current sensor M2 immediately before the occurrence of the short circuit can be used to specify the short-circuit portion without performing the inspection power supply. As described above, the short-circuit portion during the external power supply may be specified by using the current sensor M1 and the current sensor M2 immediately before the occurrence of the short-circuit without performing the test power supply.

The embodiments disclosed herein are illustrative and not restrictive in all respects. The scope of the present disclosure is defined by the terms of the claims, rather than the description of the embodiments described above, and includes all modifications within the scope equivalent to the terms of the claims.

What is claimed is:

1. Electric equipment connected between at least one of an electric load and a power grid, and a vehicle equipped with a power storage device, the electric equipment comprising:
a first current sensor for detecting a current on a power line connected to the vehicle;
a second current sensor for detecting a current on a power line connected to the one of the electric load or the power grid;
a communication unit for performing communication with the vehicle; and
a control device, wherein when short-circuiting occurs in a circuit including the one of the electric load or the power grid and the electric equipment, the control device identifies a short-circuiting location based on a detection value of the first current sensor and a detection value of the second current sensor, and transmits information of the short-circuiting location to the vehicle by the communication unit.

2. The electric equipment according to claim 1, wherein the control device identifies the short-circuiting location as being the electric load or the power grid, when a current is detected by the first current sensor and the second current sensor by electric power supplied from the power storage device to the electric equipment, and identifies the short-circuiting location as being the electric equipment when a current is detected by the first current sensor alone.

3. The electric equipment according to claim 1, wherein:
the electric equipment is configured such that
electric power is exchangeable between the power storage device and the electric equipment when a connector of the electric equipment is connected to an inlet of the vehicle, and also
communication is performed with the vehicle using a signal line that is connected when the connector is connected to the inlet; and
the communication unit transmits the information regarding the short-circuiting location to the vehicle using the signal line.

4. A vehicle connected to the electric equipment according to claim 1, the vehicle comprising:
a vehicle-side control device; and
a notification device, wherein the vehicle-side control device performs notification regarding the short-circuiting location, based on the information of the short-circuiting location received from the communication unit.
